(19) United States
(12) Patent Application Publication
(10) Pub. No.: US 2013/0050043 A1
(43) Pub. Date: Feb. 28, 2013

(54) ARTIFICIAL MAGNETIC CONDUCTOR USING COMPLEMENTARY TILINGS

(71) Applicant: Frank Blackburn Gross, III, Round Hill, VA (US)

(72) Inventor: Frank Blackburn Gross, III, Round Hill, VA (US)

(73) Assignee: The Boeing Company, Chicago, IL (US)

(21) Appl. No.: 13/222,618

(22) Filed: Aug. 31, 2011

(51) Int. Cl. H01Q 19/10; H05K 3/40; H05K 3/02; H01Q 15/14

(52) U.S. Cl. 343/834; 343/912; 29/846; 29/847

(57) ABSTRACT

A device includes a ground plane, a substrate coupled to the ground plane, and a patterned layer on a surface of the substrate. The patterned layer includes multiple conductive regions, where adjacent conductive regions of the multiple conductive regions are coupled to one another. The patterned layer also includes multiple non-conductive regions interspersed with the multiple conductive regions. The multiple non-conductive regions are complementary to the multiple conductive regions.

### FIELD OF THE DISCLOSURE

The present disclosure is generally related to an artificial magnetic conductor.

### BACKGROUND

Artificial magnetic conductors, also referred to as high impedance surfaces, may be applied over a ground plane in order to modify reflection characteristics of the ground plane with respect to signals at certain frequencies. Such high impedance surfaces normally have narrow relative bandwidths. Within a particular narrow frequency range corresponding to the relative bandwidth, the high impedance surface may reflect an incoming signal nearly in-phase with respect to the incoming signal. Outside of this narrow frequency range, (e.g., below an in-phase reflection frequency or above the in-phase reflection frequency), the incoming signal may be reflected out of phase. Out of phase reflections cause constructive and destructive interference with the incoming signal, and accordingly it may be desirable to avoid out of phase reflections.

### SUMMARY

An artificial magnetic conductor may include a patterned top layer having a complementary pattern. While artificial magnetic conductors typically achieve in-phase reflection relative bandwidths of less than 2:1, particular embodiments described herein achieve in-phase reflection relative bandwidths of 3:1 or greater. Particular embodiments described herein include artificial magnetic conductors having complementary tiling patterns. One realization is the Thue-Morse tiling pattern. Such a complementary tiling pattern provides increased relative bandwidth of antenna structures utilizing the high impedance surface over a ground plane. Additionally, or in the alternative, the high impedance device may be selectively coupled to an underlying structure in order to decrease the radar reflection from that structure.

Complementary tiling patterns may include conductive areas and complementary or substantially complementary non-conductive areas. The conductive areas and substantially complementary non-conductive areas may be of the same size and shape. Additionally, each conductive area may be coupled to one or more adjacent conductive areas (at a vertex of the conductive area and at a vertex of the adjacent conductive area) to form a substantially electrically continuous patterned layer. Small gaps at the vertices may also be introduced to produce variations on the performance. In addition, the patterned layer may be electrically coupled to an underlying ground plane by one or more vias or conductive elements. Alternatively, the patterned layer may be electrically isolated from and not physically coupled to the ground plane.

In another particular embodiment, a method includes coupling a substrate having a surface to a ground plane and forming a patterned layer on the surface of the substrate. The patterned layer includes multiple conductive regions, where adjacent conductive regions of the multiple conductive regions are coupled to one another. The patterned layer also includes multiple non-conductive regions interspersed with the multiple conductive regions. The multiple non-conductive regions are substantially complementary to the multiple conductive regions.

In another particular embodiment, an antenna system includes an antenna element and an artificial magnetic conductor device. The artificial magnetic conductor device includes a ground plane, a substrate coupled to the ground plane, and a patterned layer on a surface of the substrate. The patterned layer includes multiple conductive regions, where adjacent conductive regions of the multiple conductive regions are coupled to one another. The patterned layer also includes multiple non-conductive regions interspersed with the multiple conductive regions. The multiple non-conductive regions are substantially complementary to the multiple conductive regions.

The features, functions, and advantages that have been described can be achieved independently in various embodiments or may be combined in yet other embodiments, further details of which are disclosed with reference to the following description and drawings.

### BRIEF DESCRIPTION OF THE DRAWINGS

FIG. 1 is a block diagram of a particular embodiment of a system including a patterned layer to form an artificial magnetic conductor;

FIG. 2 illustrates particular embodiments of substantially complementary tiling patterns that may be used for the patterned layer of FIG. 1;

FIG. 3 illustrates simulated performance of an artificial magnetic conductor structure generated using a second generation Thue-Morse tiling pattern;

FIG. 4 illustrates simulated performance of an artificial magnetic conductor structure generated using a third generation Thue-Morse tiling pattern;

FIG. 5 illustrates simulated performance of an artificial magnetic conductor structure generated using a fourth generation Thue-Morse tiling pattern; and

FIG. 6 is a flow diagram of a particular embodiment of a method of generating an artificial magnetic conductor.

### DETAILED DESCRIPTION

An artificial magnetic conductor (also referred to as a high impedance surface) includes a patterned layer having a complementary pattern, such as a Thue-Morse tiling pattern. Such complementary tiling patterns provide increased relative bandwidth of antenna structures utilizing the high impedance surface coupled to a ground plane. Additionally, or in the alternative, the high impedance surface may be coupled to an underlying structure in order to modify the radar reflection characteristic of the structure. By using conductive regions and complementary non-conductive regions, an artificial magnetic conductor having an in-phase reflection relative bandwidth of 2:1, 2.5:1, or even 3:1 or higher can be achieved. Thus, high impedance surfaces may be useful to reduce out of phase reflections in certain frequencies.

Artificial magnetic conductors include a particular type of metamaterial surface that provides a positive reflection coefficient over a finite bandwidth referred to herein as the in-phase reflection relative bandwidth. Accordingly, the artificial magnetic conductor behaves as a magnetic conductor rather than as an electric conductor within this finite bandwidth. The artificial magnetic conductor may also be referred to as an electro-magnetic bandgap structure, a high impedance surface, a perfect magnetic conductor, and a specific type of metamaterial or frequency selective surface. An artificial magnetic conductor may be formed by placing a frequency selective surface a fraction of a wavelength over a conductive ground plane. When the frequency selective surface is placed over a conductive ground plane, an engineered reflective surface phase can be generated. For example, the frequency selective surface may include a patterned layer separated from the ground plane by a substrate. The patterned layer may be above the ground plane at a height approximately 1/20^{th} of a target wavelength of a target signal.

Typical artificial magnetic conductors include a plurality of conductive elements having a particular geometric shape, such as square patches, circular discs, triangles, polygons, and pixilated structures. Each conductive element may or may not be coupled to the ground plane by a pin or via. Accordingly, the artificial magnetic conductors may be described as having a mushroom or thumbtack shape descriptive of a shape of the conductive element coupled to the ground plane by the pin. Various shapes and geometries of the conductive element may affect performance of the artificial magnetic conductor. For example, various shapes and complexities, including shapes within a single plane and shapes within multiple planes, may increase or decrease the in-phase reflection relative bandwidth or a center frequency of the artificial magnetic conductor. A typical in-phase reflection relative bandwidth for thumbtack structures may be approximately 1.5:1.

Artificial magnetic conductors with the thumbtack or mushroom shapes may operate within a relatively narrow in-phase reflection relative bandwidth. Embodiments disclosed herein include a ground plane, a substrate coupled to the ground plane, and a patterned layer on a surface of the substrate. The patterned layer may include multiple conductive regions and multiple non-conductive regions where adjacent conductive regions of the multiple conductive regions are coupled to one another. As used herein, adjacent refers to sharing a common boundary or meeting at a common vertex. For example, the adjacent conductive regions may be coupled at vertices of the conductive regions. The multiple non-conductive regions are interspersed between and among the multiple conductive regions. In particular, the multiple non-conductive regions are complementary to the multiple conductive regions. As used herein, complementary refers to having a same shape and size as the multiple conductive regions. Thus, a non-conductive region is complementary to a conductive region when the non-conductive region has the same shape and size as the conductive region. Substantially complementary indicates that minor variations may be present such as minor design or manufacturing variations that deviate from complementary by a small margin. Examples of complementary patterns include Thue-Morse complementary tiling patterns. Other examples of complementary patterns include regular tessellations. By using conductive regions and complementary non-conductive regions, an artificial magnetic conductor having an in-phase reflection relative bandwidth of 2:1, 2.5:1, or even 3:1 or higher can be achieved. In addition, embodiments disclosed herein do not use a via or a pin to couple the patterned layer to the ground plane (e.g., in an antenna system), thereby simplifying the manufacturing process and reducing cost.

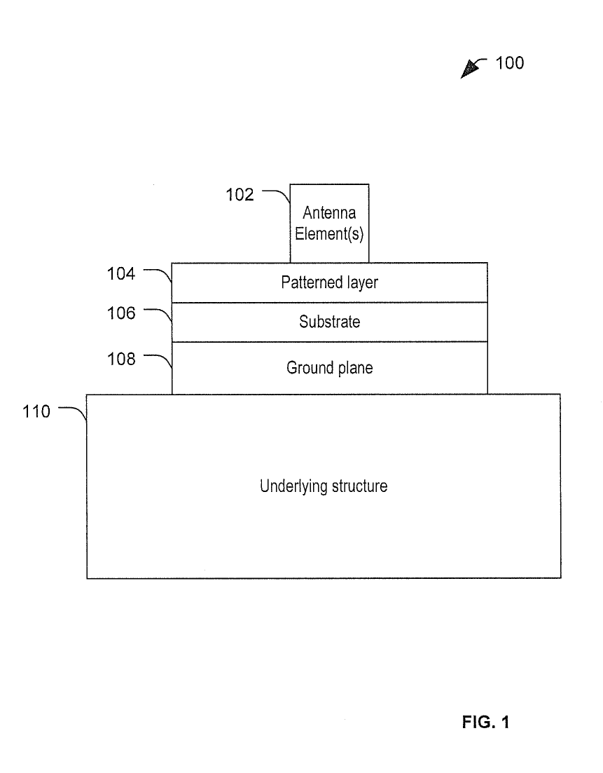

FIG. 1 illustrates a particular embodiment of a system 100 including a patterned layer to form an artificial magnetic conductor. The system 100 includes a patterned layer 104 on a surface of a substrate 106. The patterned layer 104 is separated from a ground plane 108 by the substrate 106. The substrate 106 may have a thickness substantially less than a wavelength of a target signal. For example, where the system 100 includes an antenna having one or more antenna elements 102, the substrate 106 may have a thickness substantially less than a wavelength of a signal to be generated by the one or more antenna elements 102. In another example, where the system 100 is coupled to an underlying structure 110 that is to be shielded from or protected from an incoming signal, the substrate 106 may have a thickness substantially less than a wavelength of a signal from which the underlying structure 110 is to be protected. In a particular embodiment, the underlying structure 110 may be conductive. In that case, the underlying structure 110 may act as a ground plane, thereby obviating the need for separate underlying structure and ground plane layers.

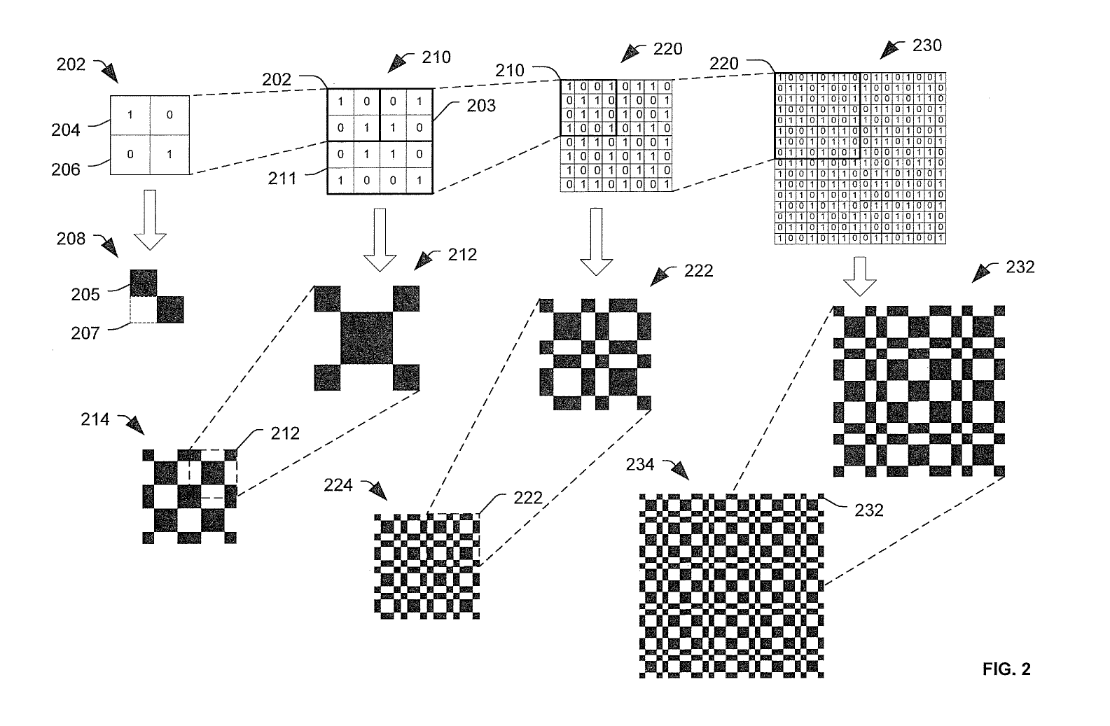

The patterned layer 104 may include multiple conductive regions and multiple non-conductive regions, forming a frequency selective surface. The multiple conductive regions may be formed such that adjacent conductive regions of the multiple conductive regions are coupled to one another. For example, the adjacent conductive regions may be coupled at vertices. To illustrate, each conductive region may be coupled to an adjacent conductive region at a vertex of the conductive region and at a vertex of the adjacent conductive region as further described with reference to FIG. 2. The multiple non-conductive regions may be interspersed with the multiple conductive regions. In particular, the multiple conductive regions may be substantially complementary to the multiple non-conductive regions. For example, in the patterned layer 104, the multiple conductive regions and the multiple non-conductive regions may be arranged in a Thue-Morse complementary tiling pattern. As an example of a Thue-Morse tiling pattern, the multiple conductive regions and the multiple non-conductive regions in the patterned layer 104 may be arranged in second generation or higher Thue-Morse complementary tiling patterns. In another example, the multiple conductive regions and the multiple non-conductive regions may be arranged in a regular tessellation of substantially complementary regions. In another example, the patterned layer 104 may include a plurality of unit cells including one or more conductive regions and one or more substantially complementary non-conductive regions, where each unit cell is adjacent to at least one identical or substantially complementary unit cell. In a particular embodiment, an artificial magnetic conductor device may include one or more substrates, where each substrate has a surface with a patterned layer thereon that includes multiple conductive regions and multiple non-conductive regions arranged in a complementary or substantially complementary pattern as described above.

In a particular embodiment, the substrate 106 includes a magnetic material. In another particular embodiment, the substrate 106 includes a dielectric material, such as silicon, ceramic, or quartz. In other particular embodiments, the substrate 106 includes a conductive polymer or a dielectric polymer. Additionally, in a particular embodiment, no conductive path is present between the multiple conductive regions of the patterned layer 104 and the ground plane 108. For example, in a particular embodiment, no vias through the substrate 106 electrically connect the patterned layer 104 and the ground plane 108. In an alternate embodiment, one or more vias or electrical connectors may couple the patterned layer 104 through the substrate 106 to the ground plane 108.

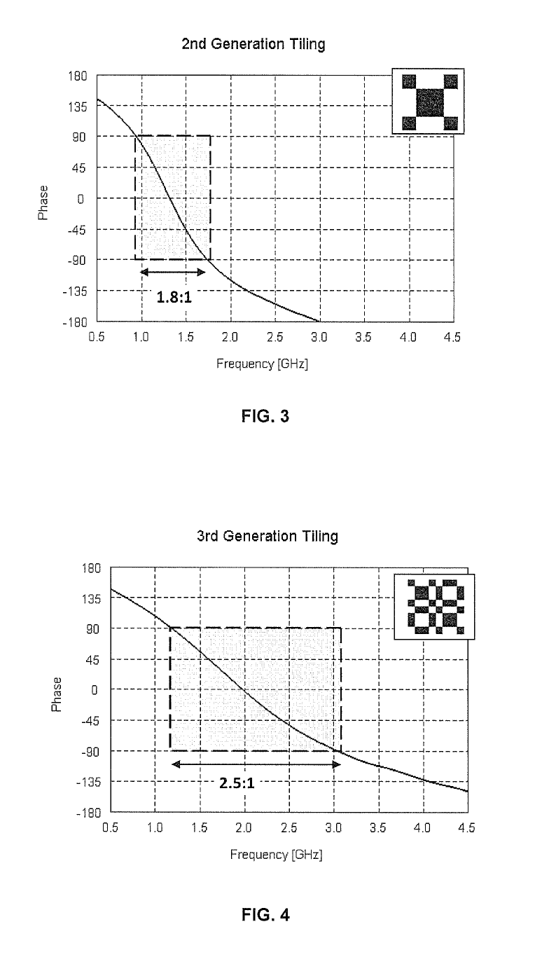

As illustrated by simulations described with reference to FIGS. 3-5, the patterned layer 104 that includes the substantially complementary conductive and non-conductive regions coupled to the substrate 106 and to the ground plane 108 may form an artificial magnetic conductor with an in-phase reflection relative bandwidth of at least 2:1, an in-phase reflection relative bandwidth of at least 2.5:1, or an in-phase reflection relative bandwidth of at least 3:1 depending on a particular configuration and a particular generation of the tiling pattern.

FIG. 2 illustrates particular embodiments of substantially complementary tiling patterns that may be used for the patterned layer 104 of FIG. 1. In particular, FIG. 2 illustrates a first generation Thue-Morse sequence 202. The first generation Thue-Morse sequence 202 includes a first row 204 and a second row 206. The first row 204 and the second row 206 are complementary to one another. To generate a first generation Thue-Morse pattern 208, values of the Thue-Morse sequences may be assigned as conductive regions and non-conductive regions. For purposes of illustration in FIG. 2, a value of “1” in a Thue-Morse sequence corresponds to a conductive region and a value of “0” in a Thue-Morse sequence corresponds to a non-conductive region. Thus, the first generation Thue-Morse pattern 208 may be formed by generating a conductive region 205 corresponding to values of “1” in the first generation Thue-Morse sequence 202 and a non-conductive region 207 corresponding to values of “0” in the first generation Thue-Morse sequence 202.

For purposes of illustration, the first generation Thue-Morse sequence 202 is illustrated as a 2×2 matrix having the first row 204 and the second row 206. To generate the first generation Thue-Morse sequence 202, binary values are assigned to each column of the first row 204. Subsequently, complementary values are assigned to corresponding columns of the second row 206. That is, where a value of “1” appears in a column of the first row 204, a value of “0” is placed in a corresponding column in the second row 206.

A second generation Thue-Morse sequence 210 may be generated as a 4×4 matrix. To generate the 4×4 matrix of the second generation Thue-Morse sequence 210, the first generation Thue-Morse sequence 202 may be replicated and a complement of the first generation Thue-Morse sequence 202 may be formed, as illustrated at 203. In the complement 203, each value of the first generation Thue-Morse sequence 202 is replaced by a complement of the particular value. For example, in the first generation Thue-Morse sequence 202, the first row 204 includes the binary values “1 0” and the first row of the complement 203 includes the binary values “0 1”. After forming the complement 203, the complement 203 and the first generation Thue-Morse sequence 202 may be joined, and a complement of the joined first generation Thue-Morse sequence 202 and the complement 203 may be formed, as illustrated at 211.

A second generation Thue-Morse pattern 212 may be determined based on the second generation Thue-Morse sequence 210. In a particular embodiment, the second generation Thue-Morse pattern 212 may be used as a unit cell to form a second generation Thue-Morse tiling pattern 214. For example, two or more identical second generation Thue-Morse patterns 212 may be used to form the second generation Thue-Morse tiling pattern 214. In a particular embodiment, the second generation Thue-Morse pattern 212 may be used as the patterned layer 104 of FIG. 1. In another particular embodiment, the second generation Thue-Morse tiling pattern 214 may be used as the patterned layer 104 of FIG. 1.

To generate a third generation Thue-Morse sequence 220, the process used to generate the second generation Thue-Morse sequence 210 may be repeated using the second generation Thue-Morse sequence 210 as a starting point. For example, the second generation Thue-Morse sequence 210 may be appended to its complement, and a complement of the resulting second generation Thue-Morse sequence 210 appended to its complement may be joined thereto to generate the third Thue-Morse sequence 220. A third generation Thue-Morse pattern 222 may be determined based on the third generation Thue-Morse sequence 220. The third generation Thue-Morse pattern 222 may be used as a unit cell to form a third generation Thue-Morse tiling pattern 224. For example, two or more identical third generation Thue-Morse patterns 222 may be used to form the third generation Thue-Morse tiling pattern 224. In a particular embodiment, the third generation Thue-Morse pattern 222 may be used as the patterned layer 104 of FIG. 1. In another particular embodiment, the third generation Thue-Morse tiling pattern 224 may be used as the patterned layer 104 of FIG. 1.

To generate a fourth generation Thue-Morse sequence 230, the process used to generate the third generation Thue-Morse sequence 220 may be repeated using the third generation Thue-Morse sequence 220 as a starting point. For example, the third generation Thue-Morse sequence 220 may be appended to its complement, and a complement of the resulting third generation Thue-Morse sequence 220 appended to its complement may be joined thereto to generate the fourth Thue-Morse sequence 230. A fourth generation Thue-Morse pattern 232 may be determined based on the fourth generation Thue-Morse sequence 230. The fourth generation Thue-Morse pattern 232 may be used as a unit cell to form a fourth generation Thue-Morse tiling pattern 234. For example, two or more identical fourth generation Thue-Morse patterns 232 may be used to form the third generation Thue-Morse tiling pattern 234. In a particular embodiment, the fourth generation Thue-Morse pattern 232 may be used as the patterned layer 104 of FIG. 1. In another particular embodiment, the fourth generation Thue-Morse tiling pattern 234 may be used as the patterned layer 104 of FIG. 1.

Although the tiling patterns and the patterned surfaces illustrated in FIG. 2 start from the 2×2 matrix of the first generation Thue-Morse sequence 202, the tiling patterns and the patterned surfaces may be formed using any size matrix. In addition, other regular tessellation patterns may be used rather than Thue-Morse complementary tiling patterns. Thus, the tiling patterns and the patterned surfaces may be composed of an equal number and area of conductive regions and non-conductive regions, respectively. When a particular tiling pattern is used as a unit cell in a repeating array, each conductive area may be adjacent to an area of its complement, e.g., areas of equal size and shape. For example, each conductive area may be adjacent to a complementary non-conductive area. Further, each conductive area may be coupled to one or more other conductive areas at vertices of the conductive areas. In addition, certain patterns may be symmetrical and other patterns may be asymmetrical. For example, using Thue-Morse patterns, even ordered generations (e.g., the second generation Thue-Morse pattern 212 and the fourth generation Thue-Morse pattern 232) may tile symmetrically while odd ordered generations (e.g., the first generation Thue-Morse pattern 208 and the third generation Thue-Morse pattern 222) may tile asymmetrically.

FIG. 3 illustrates simulated performance of an artificial magnetic conductor structure using a second generation Thue-Morse tiling pattern. In particular, the artificial magnetic conductor was simulated using a patterned layer above a ground plane where the patterned layer is formed from the second generation Thue-Morse tiling pattern 214 illustrated in FIG. 2. The patterned layer was simulated as having a height above the ground plane of approximately 1/15^{th} of a wavelength of a target signal. The second generation Thue-Morse tiling pattern 214 was simulated as having a period from cell-to-cell or from conductive area to conductive area of approximately 29/100 of a wavelength of the target signal. The period and the height above the ground plane may be changed for particular embodiments in order to shift a target frequency or to tune the target frequency or resonant frequency of the artificial magnetic conductor. As shown in FIG. 3, the in-phase reflection relative bandwidth was measured between a frequency at which the artificial magnetic conductor has a reflection that generates a reflection phase of 90 degrees and a frequency at which the artificial magnetic conductor generates a reflection phase of −90 degrees. FIG. 3 indicates that the in-phase reflection relative bandwidth of the simulated artificial magnetic conductor using the second generation Thue-Morse tiling pattern 214 is approximately 1.8:1.

FIG. 4 illustrates simulated performance of an artificial magnetic conductor structure using a third generation Thue-Morse tiling pattern. In particular, the artificial magnetic conductor was simulated using a patterned layer above a ground plane where the patterned layer is formed from the third generation Thue-Morse tiling pattern 224 illustrated in FIG. 2. As described above, the patterned layer was simulated as having a height above the ground plane of approximately 1/15^{th} of a wavelength of a target signal, and the third generation Thue-Morse tiling pattern 224 was simulated as having a period from cell-to-cell or from conductive area to conductive area of approximately 29/100 of a wavelength of the target signal. The period and the height above the ground plane may be changed for particular embodiments in order to shift a target frequency or tune the target frequency or resonant frequency of the artificial magnetic conductor. As shown in FIG. 4, the in-phase reflection relative bandwidth was measured between a frequency at which the artificial magnetic conductor has a reflection that generates a reflection phase of 90 degrees and a frequency at which the artificial magnetic conductor generates a reflection phase of −90 degrees. FIG. 4 indicates that the in-phase reflection relative bandwidth of the simulated artificial magnetic conductor using the third generation Thue-Morse tiling pattern 224 is approximately 2.5:1.

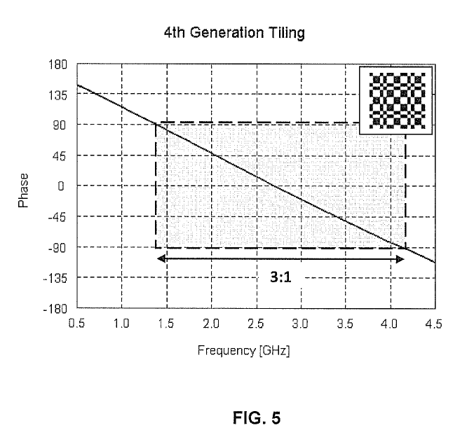

FIG. 5 illustrates simulated performance of an artificial magnetic conductor structure using a fourth generation Thue-Morse tiling pattern. In particular, the artificial magnetic conductor was simulated using a patterned layer above a ground plane where the patterned layer is formed from the fourth generation Thue-Morse tiling pattern 234 illustrated in FIG. 2. As described above, the patterned layer was simulated as having a height above the ground plane of approximately 1/15^{th} of a wavelength of a target signal, and the fourth generation Thue-Morse tiling pattern 234 was simulated as having a period from cell-to-cell or from conductive area to conductive area of approximately 29/100 of a wavelength of the target signal. The period and the height above the ground plane may be changed for particular embodiments in order to shift a target frequency or to tune the target frequency or resonant frequency of the artificial magnetic conductor. As shown in FIG. 5, the in-phase reflection relative bandwidth was measured between a frequency at which the artificial magnetic conductor has a reflection that generates a reflection phase of 90 degrees and a frequency at which the artificial magnetic conductor generates a reflection phase of −90 degrees. FIG. 5 indicates that the in-phase reflection relative bandwidth of the simulated artificial magnetic conductor using the fourth generation Thue-Morse tiling pattern 234 is approximately 3:1.

An artificial magnetic conductor structure using a patterned layer, such as a structure including a patterned layer formed from one of a second generation Thue-Morse tiling pattern, a third generation Thue-Morse tiling pattern, a fourth generation Thue-Morse tiling pattern, or higher generation Thue-Morse tiling pattern, may produce an artificial magnetic conductor structure that has an in-phase reflection relative bandwidth that is greater than a corresponding relative bandwidth for conventional artificial magnetic conductor structures.

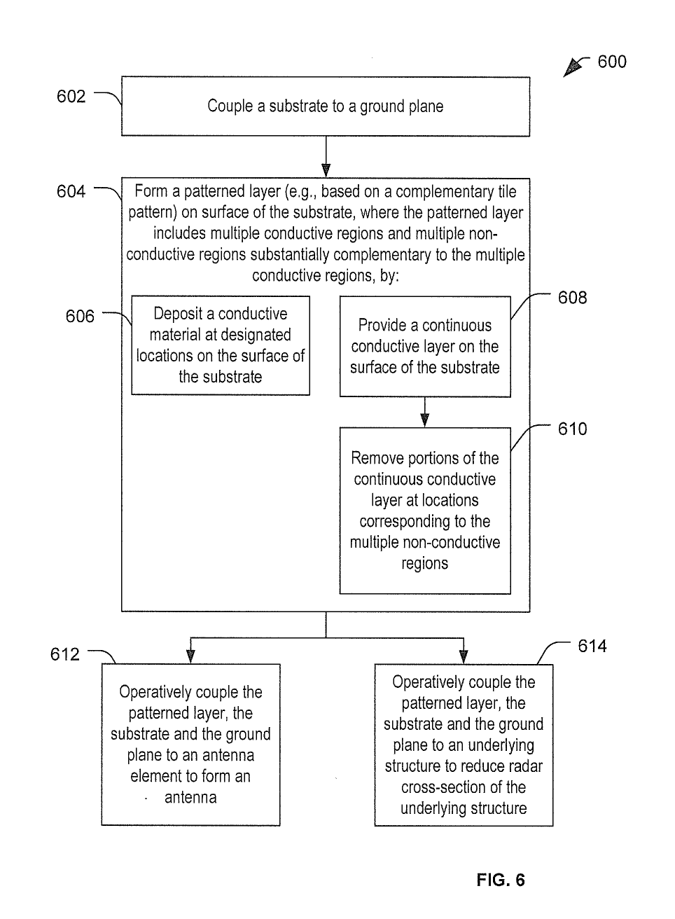

FIG. 6 illustrates a particular embodiment of a method 600 of generating an artificial magnetic conductor. The method 600 includes coupling a substrate to a ground plane, at 602. In a particular embodiment, the substrate may be the substrate 106 of FIG. 1 and the ground plane may be the ground plane 108 of FIG. 1. In another particular embodiment, the substrate may be previously formed on the ground plane. The method may also include, at 604, forming a patterned layer on the substrate. The patterned layer includes multiple conductive regions, where adjacent conductive regions of the multiple conductive regions are coupled to one another. The patterned layer also includes multiple non-conductive regions interspersed with the multiple conductive regions. The multiple non-conductive regions may be substantially complementary to the multiple conductive regions. In a particular embodiment, the patterned layer may be the patterned layer 104 of FIG. 1 or a patterned layer formed by use of the first generation Thue-Morse pattern 208 of FIG. 2, the second generation Thue-Morse tiling pattern 214 of FIG. 2, the third generation Thue-Morse tiling pattern 224 of FIG. 2, or the fourth generation Thue-Morse tiling pattern 234 of FIG. 2. The patterned layer may alternatively be a pattern arranged in a regular tessellation of substantially complementary regions.

The patterned layer may be formed by various methods. For example, in a particular embodiment, the patterned layer may be formed by depositing a conductive material on the substrate at desired locations to form the patterned layer, at 606. For example, a mask may be placed on the substrate and the conductive material may be deposited thereafter. In another particular embodiment, the patterned layer may be formed by placing a continuous conductive layer on the substrate, at 608, and by removing portions of the continuous conductive layer at locations corresponding to the multiple non-conductive regions, at 610. For example, portions of the continuous conductive layer may be removed by an etching process. After the patterned layer is formed on the substrate, an artificial magnetic conductor device, which includes the patterned layer, the substrate, and the ground plane, may be operatively coupled to an antenna element to form an antenna, at 612. In a particular embodiment, the antenna element may be the antenna element 102 of FIG. 1. As another example, after the patterned layer is formed on the substrate, the artificial magnetic conductor may be coupled to an underlying structure to reduce a radar cross-section of the underlying structure, at 614. In a particular embodiment, the underlying structure may be the underlying structure 110 of FIG. 1.

An artificial magnetic conductor that includes a patterned layer having a complementary pattern, such as Thue-Morse tiling patterns, may provide increased relative bandwidth of antenna structures that utilize the artificial magnetic conductor. Additionally, the artificial magnetic conductor may be coupled to an underlying structure in order to change (e.g., decrease) a radar reflection characteristic of the structure. By using conductive regions and substantially complementary non-conductive regions, an artificial magnetic conductor having an in-phase reflection relative bandwidth of 2:1, 2.5:1, or even 3:1 or higher can be achieved.

The illustrations of the embodiments described herein are intended to provide a general understanding of the structure of the various embodiments. The illustrations are not intended to serve as a complete description of all of the elements and features of apparatus and systems that utilize the structures or methods described herein. Many other embodiments may be apparent to those of skill in the art upon reviewing the disclosure. For example, patterns have been illustrated herein with generally rectangular elements, but the elements may be in the form of other shapes such as a square, a circle, a triangle, a polygon, or any other shape. Other embodiments may be utilized and derived from the disclosure, such that structural and logical substitutions and changes may be made without departing from the scope of the disclosure. Additionally, the illustrations are merely representational and may not be drawn to scale. Certain proportions within the illustrations may be exaggerated, while other proportions may be reduced. Accordingly, the disclosure and the figures are to be regarded as illustrative rather than restrictive.

One or more embodiments of the disclosure may be referred to herein, individually and/or collectively, by the term “invention” merely for convenience and without intending to voluntarily limit the scope of this application to any particular concept. Moreover, although specific embodiments have been illustrated and described herein, it should be appreciated that any subsequent arrangement designed to achieve the same or similar purpose may be substituted for the specific embodiments shown. This disclosure is intended to cover any and all subsequent adaptations or variations of various embodiments. Combinations of the above embodiments, and other embodiments not specifically described herein, will be apparent to those of skill in the art upon reviewing the description.

The Abstract of the Disclosure is provided with the understanding that it will not be used to interpret or limit the scope or meaning of the claims. In addition, in the foregoing Detailed Description, various features may be grouped together or described in a single embodiment for the purpose of streamlining the disclosure. This disclosure is not to be interpreted as reflecting an intention that the claimed embodiments require more features than are expressly recited in each claim. Rather, as the following claims reflect, claimed subject matter may be directed to less than all of the features of any of the disclosed embodiments. Thus, the following claims are incorporated into the Detailed Description, with each claim standing on its own as defining separately claimed subject matter.

The above-disclosed subject matter is to be considered illustrative, and not restrictive, and the appended claims are intended to cover all such modifications, enhancements, and other embodiments, which fall within the scope of the present disclosure. Thus, to the maximum extent allowed by law, the scope of the disclosure is to be determined by the broadest permissible interpretation of the following claims and their equivalents, and shall not be restricted or limited by the foregoing detailed description.

What is claimed is:

1. An artificial magnetic conductor device comprising:
a ground plane;
a substrate having a surface, the substrate coupled to the ground plane; and
a patterned layer on the surface of the substrate, the patterned layer including:
multiple conductive regions, wherein adjacent conductive regions of the multiple conductive regions are coupled to one another; and
multiple non-conductive regions interspersed with the multiple conductive regions, wherein the multiple non-conductive regions are substantially complementary to the multiple conductive regions.

2. The artificial magnetic conductor device of claim 1, wherein the patterned layer forms a frequency selective surface with an in-phase reflection relative bandwidth of at least 2:1.

3. The artificial magnetic conductor device of claim 1, wherein the patterned layer forms a frequency selective surface with an in-phase reflection relative bandwidth of at least 2.5:1.

4. The artificial magnetic conductor device of claim 1, wherein the patterned layer forms a frequency selective surface with an in-phase reflection relative bandwidth of at least 3:1.

5. The artificial magnetic conductor device of claim 1, wherein the multiple conductive regions and the multiple non-conductive regions are arranged in a Thue-Morse complementary tiling pattern.

6. The artificial magnetic conductor device of claim 1, wherein the multiple conductive regions and the multiple non-conductive regions are arranged in a regular tessellation of substantially complementary regions.

7. The artificial magnetic conductor device of claim 1, wherein the multiple conductive regions and the multiple non-conductive regions are arranged in a second generation or higher Thue-Morse complementary tiling pattern.

8. The artificial magnetic conductor device of claim 1, wherein the patterned layer is electrically isolated from the ground plane.

9. The artificial magnetic conductor device of claim 1, wherein the substrate comprises a magnetic material.

10. The artificial magnetic conductor device of claim 1, wherein the substrate comprises a dielectric material.

11. The artificial magnetic conductor device of claim 1, wherein each conductive region of the multiple conductive regions is coupled to an adjacent conductive region of the multiple conductive regions at vertices of the conductive region and the adjacent conductive region.

12. The artificial magnetic conductor device of claim 1, wherein the patterned layer comprises a plurality of unit cells and wherein each unit cell is adjacent to at least one complementary unit cell.

13. A method comprising:
coupling a substrate to a ground plane; and
forming a patterned layer on a surface of the substrate, wherein the patterned layer includes:
multiple conductive regions, wherein adjacent conductive regions of the multiple conductive regions are coupled to one another; and
multiple non-conductive regions interspersed with the multiple conductive regions, wherein the multiple non-conductive regions are substantially complementary to the multiple conductive regions.

14. The method of claim 13, wherein the patterned layer is formed by depositing a conductive material on the surface of the substrate.

15. The method of claim 13, wherein the patterned layer is formed by depositing a continuous conductive layer on the surface of the substrate and removing portions of the continuous conductive layer at locations corresponding to the multiple non-conductive regions.

16. The method of claim 13, wherein no vias through the substrate electrically connect the patterned layer and the ground plane.

17. An antenna system comprising
an antenna element;
a ground plane;
a substrate coupled to the ground plane, the substrate having a surface; and
a patterned layer on the surface of the substrate, the patterned layer including:
multiple conductive regions, wherein adjacent conductive regions of the multiple conductive regions are coupled to one another; and
multiple non-conductive regions interspersed with the multiple conductive regions, wherein the multiple non-conductive regions are substantially complementary to the multiple conductive regions.

18. The antenna system of claim 17, wherein the substrate comprises a dielectric material, and wherein the patterned layer is electrically isolated from the ground plane.

19. The antenna system of claim 17, wherein each conductive region of the multiple conductive regions is coupled to an adjacent conductive region of the multiple conductive regions at vertices of the conductive region and the adjacent conductive region.

20. The antenna system of claim 17, wherein the multiple conductive regions and the multiple non-conductive regions are arranged in a Thue-Morse complementary tiling pattern.
